(19) United States
(12) Patent Application Publication
(10) Pub. No.: US 2025/0346761 A1
(43) Pub. Date: Nov. 13, 2025

(54) RESIN COMPOSITION, PREPREG, FILM WITH RESIN, METAL FOIL WITH RESIN, METAL-CLAD LAMINATE, AND WIRING BOARD

(71) Applicant: PANASONIC INTELLECTUAL PROPERTY MANAGEMENT CO., LTD., Osaka (JP)

(72) Inventors: Hirosuke SAITO, Osaka (JP); Hajime OTSUKA, Osaka (JP)

(73) Assignee: PANASONIC INTELLECTUAL PROPERTY MANAGEMENT CO., LTD., Osaka (JP)

(21) Appl. No.: 18/878,451

(22) PCT Filed: Jun. 26, 2023
(86) PCT No.: PCT/JP2023/023667

§ 371 Date: Dec. 23, 2024

(30) Foreign Application Priority Data
Jul. 4, 2022 (JP) 2022-107976

(51) Int. Cl. C08L 79/08; C08F 283/04; C08J 5/24; C08K 3/36; C08K 5/14; C08K 5/3445

(52) U.S. Cl. CPC C08L 79/085; C08F 283/04; C08J 5/244; C08K 3/36; C08K 5/14; C08K 5/3445; C08J 2379/08; C08L 2203/16; C08L 2203/20; C08L 2205/05

(57) ABSTRACT

A resin composition contains a maleimide compound (A) having a benzene ring in the molecule and a maleimide equivalent of 500 g/mol or less; an imide compound (B) having at least one of a hydrocarbon group or a maleimide group at the molecular end; and a radical polymerizable compound (C) having a benzene ring to which an alkenyl group is bonded in the molecule and a weight average molecular weight of 1,000 or less.

### TECHNICAL FIELD

The present invention relates to a resin composition, a prepreg, a film with resin, a metal foil with resin, a metal-clad laminate, and a wiring board.

### BACKGROUND ART

In various kinds of electronic equipment, mounting technologies such as higher integration of semiconductor devices to be mounted, higher wiring density, and multi-layering have rapidly progressed along with an increase in the amount of information processed. In addition, wiring boards used in various kinds of electronic equipment, for example, antenna-in-package substrates for mobile applications, are required to be compatible with high frequencies. Substrate materials for forming insulating layers of wiring boards used in various kinds of electronic equipment are required to have a low relative dielectric constant and a low dielectric loss tangent in order to increase the signal transmission speed and to decrease the signal transmission loss.

Examples of the substrate materials for forming insulating layers of wiring boards include the resin compositions described in Patent Literatures 1 and 2.

Patent Literature 1 describes a resin composition containing a modified polyphenylene ether compound having the terminal modified with a substituent having a carbon-carbon unsaturated double bond; a maleimide compound that does not contain a phenylmaleimide group and has a hydrocarbon group having 10 or more carbon atoms in the molecule; and at least one selected from a maleimide compound containing a phenylmaleimide group or a maleimide compound having an aliphatic hydrocarbon group having 9 or less carbon atoms in the molecule. Patent Literature 1 discloses that it is possible to provide a resin composition that exhibits handleability in a prepreg or the like that contains the resin composition or a semi-cured product thereof, and low dielectric properties, high heat resistance, a high Tg, a low coefficient of thermal expansion, close contact properties, and low water absorption rate properties in a cured product of the resin composition.

Patent Literature 2 describes a resin composition containing a compound having a maleimide group, a divalent group having at least two imide bonds, and a saturated or unsaturated divalent hydrocarbon group. Patent Literature 2 discloses that it is possible to provide a resin composition that exhibits excellent high-frequency properties (low relative dielectric constant, low dielectric loss tangent) and also high levels of adhesiveness to conductors, heat resistance, and low moisture absorbing properties.

Substrate materials for forming insulating layers of wiring boards are required to afford cured products, which have not only low relative dielectric constants and dielectric loss tangents but also sufficiently suppressed increases in relative dielectric constant and dielectric loss tangent due to water absorption and low coefficients of thermal expansion.

### CITATION LIST

### Patent Literatures

Patent Literature 1: WO 2019/188189 A
Patent Literature 2: WO 2016/114286 A

### SUMMARY OF INVENTION

The present invention has been made in view of such circumstances, and an object thereof is to provide a resin composition that affords a cured product, which has a low relative dielectric constant and a low dielectric loss tangent, sufficiently suppressed increases in relative dielectric constant and dielectric loss tangent due to water absorption, and a low coefficient of thermal expansion. Another object of the present invention is to provide a prepreg, a film with resin, a metal foil with resin, a metal-clad laminate, and a wiring board, which are obtained using the resin composition.

An aspect of the present invention is a resin composition containing a maleimide compound (A) having a benzene ring in the molecule and a maleimide equivalent of 500 g/mol or less; an imide compound (B) having at least one of a hydrocarbon group or a maleimide group at the molecular end; and a radical polymerizable compound (C) having a benzene ring to which an alkenyl group is bonded in the molecule and a weight average molecular weight of 1,000 or less.

The objects and other objects, features and advantages of the present invention will become apparent from the following detailed description and accompanying drawings.

### BRIEF DESCRIPTION OF DRAWINGS

FIG. 1 is a schematic sectional view illustrating an example of a prepreg according to an embodiment of the present invention.

FIG. 2 is a schematic sectional view illustrating an example of a metal-clad laminate according to an embodiment of the present invention.

FIG. 3 is a schematic sectional view illustrating an example of a wiring board according to an embodiment of the present invention.

FIG. 4 is a schematic sectional view illustrating an example of a metal foil with resin according to an embodiment of the present invention.

FIG. 5 is a schematic sectional view illustrating an example of a film with resin according to an embodiment of the present invention.

### DESCRIPTION OF EMBODIMENTS

Metal-clad laminates and metal foils with resin used in the manufacture of wiring boards and the like include not only an insulating layer but also a metal foil on the insulating layer. Wiring boards also include not only an insulating layer but also wiring on the insulating layer. Examples of the wiring include wiring derived from a metal foil equipped in the metal-clad laminate or the like.

Wiring boards used in various kinds of electronic equipment are also required to be hardly affected by changes of the external environment, and the like. For example, insulating layers of wiring boards are required to have small variations in relative dielectric constant and dielectric loss tangent due to changes in humidity so that the wiring boards can be used in a highly humid environment as well. Hence, substrate materials for forming insulating layers of wiring boards are required to afford cured products, which have sufficiently suppressed increases in relative dielectric constant and dielectric loss tangent due to moisture absorption and small variations in relative dielectric constant and dielectric loss tangent due to changes in humidity. More specifically, substrate materials for forming insulating layers of wiring boards are required to afford cured products, which have sufficiently suppressed increases in relative dielectric constant and dielectric loss tangent due to water absorption.

The wiring boards are also required to be hardly affected by reflow treatment and the like during mounting. For example, wiring boards are required to include insulating layers that are hardly deformed by reflow treatment and the like so that the wiring boards can be used without problems when subjected to reflow treatment as well. In other words, the insulating layers are required to be hardly deformed by temperature changes such as heating during reflow treatment. In particular, as thinning of semiconductor package substrates among wiring boards proceeds, problems arise that warpage of semiconductor packages on which semiconductor chips are mounted occurs and mounting failures are likely to occur. In order to suppress warpage of semiconductor packages, the insulating layers are required to have a low coefficient of thermal expansion. Hence, substrate materials for forming insulating layers of wiring boards are required to afford cured products having a low coefficient of thermal expansion.

Furthermore, in order to suppress loss due to increased resistance accompanying refinement of wiring, the insulating layers equipped in wiring boards are required to have a lower relative dielectric constant and a lower dielectric loss tangent.

For these reasons, substrate materials of wiring boards and the like are required to afford cured products, which have lower relative dielectric constants and lower dielectric loss tangents, sufficiently suppressed increases in relative dielectric constant and dielectric loss tangent due to water absorption, and lower coefficients of thermal expansion than the resin compositions described in Patent Literatures 1 and 2.

As a result of various investigations, the present inventors have found out that the object of providing a resin composition that affords a cured product, which has a low relative dielectric constant and a low dielectric loss tangent, sufficiently suppressed increases in relative dielectric constant and dielectric loss tangent due to water absorption, and a low coefficient of thermal expansion, can be achieved by the following present invention.

Hereinafter, embodiments according to the present invention will be described, but the present invention is not limited thereto.

### [Resin Composition]

The resin composition according to an embodiment of the present invention is a resin composition containing a maleimide compound (A) having a benzene ring in the molecule and a maleimide equivalent of 500 g/mol or less; an imide compound (B) having at least one of a hydrocarbon group or a maleimide group at the molecular end; and a radical polymerizable compound (C) having a benzene ring to which an alkenyl group is bonded in the molecule and a weight average molecular weight of 1,000 or less. As the resin composition is cured, a cured product is obtained, which has a low relative dielectric constant and a low dielectric loss tangent, sufficiently suppressed increases in relative dielectric constant and dielectric loss tangent due to water absorption, and a low coefficient of thermal expansion.

### (Maleimide Compound (a))

The maleimide compound (A) is not particularly limited as long as it is a maleimide compound, which has a benzene ring in the molecule and a maleimide equivalent of 500 g/mol or less. Examples of the maleimide compound (A) include a maleimide compound that is solid at 25° C.

The maleimide equivalent of the maleimide compound (A) is preferably 500 g/mol or less, more preferably 200 to 450 g/mol. When the maleimide equivalent is too low, the compatibility with the imide compound (B) decreases, and the maleimide compound (A) tends to be easily separated from the resin composition during preparation of a varnish. When the maleimide equivalent is too high, the cured product obtained tends to have a low glass transition temperature and a high coefficient of thermal expansion. Hence, it is preferable that the maleimide equivalent of the maleimide compound (A) is within the above range from the viewpoint of obtaining a resin composition that can be prepared into a highly uniform varnish and affords a cured product having a low coefficient of thermal expansion. Here, the maleimide equivalent is the mass per 1 mol of maleimide group, and can be calculated, for example, by dividing the molecular weight of the maleimide compound by the number of maleimide groups.

Examples of the maleimide compound (A) include a maleimide compound having an arylene structure bonded in the meta-orientation in the molecule. Examples of the arylene structure bonded in the meta-orientation include an arylene structure in which a structure containing a maleimide group is bonded at the meta position (an arylene structure in which a structure containing a maleimide group is substituted at the meta position). The arylene structure bonded in the meta-orientation is an arylene group bonded in the meta-orientation, such as a group represented by the following Formula (2). Examples of the arylene structure bonded in the meta-orientation include m-arylene groups such as a m-phenylene group and a m-naphthylene group, and more specific examples thereof include a group represented by the following Formula (2).

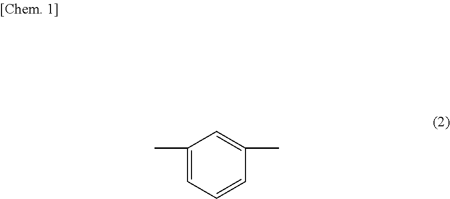

Examples of the maleimide compound (A) include a maleimide compound (A1) represented by the following Formula (3), and more specific examples thereof include a maleimide compound (A2) represented by the following Formula (4).

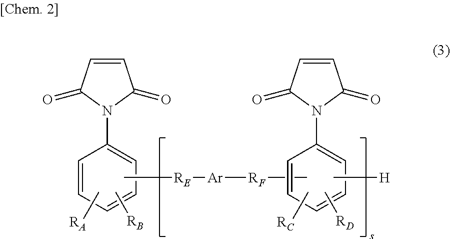

In Formula (3), Ar represents an arylene group bonded in the meta-orientation. R_{A}, R_{B}, R_{C}, and R_{D} are independent of each other. In other words, R_{A}, R_{B}, R_{C}, and R_{D} may be the same group as or different groups from each other. R_{A}, R_{B}, R_{C}, and R_{D} represent a hydrogen atom, an alkyl group having 1 to 5 carbon atoms, or a phenyl group, preferably a hydrogen atom. R_{E} and R_{F} are independent of each other. In other words, R_{E} and R_{F} may be the same group as or different groups from each other. R_{E} and R_{F} represent an aliphatic hydrocarbon group. s represents 1 to 5.

The arylene group is not particularly limited as long as it is an arylene group bonded in the meta-orientation, examples thereof include m-arylene groups such as a m-phenylene group and a m-naphthylene group, and more specific examples thereof include a group represented by Formula (2).

Examples of the alkyl group having 1 to 5 carbon atoms include a methyl group, an ethyl group, a propyl group, an isopropyl group, a n-butyl group, a sec-butyl group, an isobutyl group, a tert-butyl group, a pentyl group, and a neopentyl group.

The aliphatic hydrocarbon group is a divalent group and may be acyclic or cyclic. Examples of the aliphatic hydrocarbon group include an alkylene group, and more specific examples thereof include a methylene group, a methylmethylene group, and a dimethylmethylene group. Among these, a dimethylmethylene group is preferable.

In the maleimide compound (A1) represented by Formula (3), s, which is the number of repetitions, is preferably 1 to 5. This s is the average value of the number of repetitions (degree of polymerization).

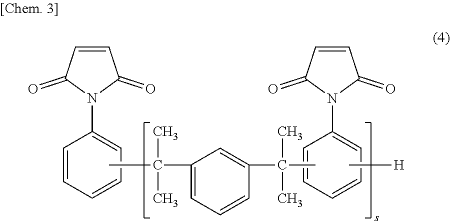

In Formula (4), s represents 1 to 5. This s is the same as s in Formula (3) and is the average value of the number of repetitions (degree of polymerization).

As long as s, which is the average value of the number of repetitions (degree of polymerization), is 1 to 5, the maleimide compound (A1) represented by Formula (3) and the maleimide compound (A2) represented by Formula (4) may include a monofunctional form in which s is 0 or a polyfunctional form such as a heptafunctional form or an octafunctional form in which s is 6 or more.

As the maleimide compound (A), a commercially available product can be used, and for example, the solid component in MIR-5000-60T manufactured by Nippon Kayaku Co., Ltd. may be used.

The maleimide compound (A) is not particularly limited as long as it is a maleimide compound, which has a benzene ring in the molecule and a maleimide equivalent of 500 g/mol or less as described above. In other words, the maleimide compound (A) may be a maleimide compound (another maleimide compound) having a benzene ring in the molecule and a maleimide equivalent of 500 g/mol or less other than the maleimide compound exemplified above. The other maleimide compound is a maleimide compound having a benzene ring in the molecule and a maleimide equivalent of 500 g/mol or less, and examples thereof include a monofunctional maleimide compound having one maleimide group in the molecule, a polyfunctional maleimide compound having two or more maleimide groups in the molecule, and a modified maleimide compound. Examples of the modified maleimide compound include a modified maleimide compound in which a part of the molecule is modified with an amine compound, a modified maleimide compound in which a part of the molecule is modified with a silicone compound, and a modified maleimide compound in which a part of the molecule is modified with an amine compound and a silicone compound. As the maleimide compound (A), the maleimide compounds exemplified above may be used singly or in combination of two or more kinds thereof. As the maleimide compound (A), the maleimide compound (A1) represented by Formula (3) may be used singly or the maleimide compound (A1) represented by Formula (3) may be used in combination of two or more kinds thereof. Examples of the combined use of two or more kinds of the maleimide compound (A1) represented by Formula (3) include concurrent use of the maleimide compound (A1) represented by Formula (3) other than the maleimide compound (A2) represented by Formula (4) with the maleimide compound (A2) represented by Formula (4).

### (Imide Compound (B))

The imide compound (B) is a compound that is different from the maleimide compound (A), and is not particularly limited as long as it is an imide compound having at least one of a hydrocarbon group or a maleimide group at the molecular end. Examples of the imide compound (B) include imide compounds having a structure represented by the following Formula (1) in the molecule.

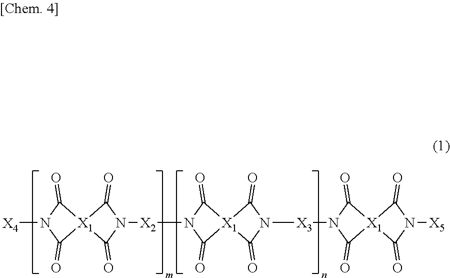

In Formula (1), X₁ represents a tetravalent tetracarboxylic acid residue. X₂ represents a divalent aliphatic diamine residue. X₃ represents a divalent aromatic diamine residue. X₄ and X₅ are independent of each other. In other words, X₄ and X₅ may be the same group as or different groups from each other. X₄ and X₅ represent a hydrocarbon group having 1 to 20 carbon atoms, a maleimide group, or an acid anhydride group, and at least one of X₄ or X₅ represents a hydrocarbon group having 1 to 20 carbon atoms or a maleimide group. m represents 1 to 50, n represents 0 to 49, and the sum of m and n represents 1 to 50. As represented by Formula (1), the imide compound (B) contains the aliphatic diamine residue in the molecule, and may also contain the aromatic diamine residue in the molecule. The imide compound (B) may be a random copolymer in which the repeating unit containing the aliphatic diamine residue and the repeating unit containing the aromatic diamine residue are present randomly.

The tetracarboxylic acid residue is not particularly limited as long as it is a tetravalent group derived from a tetracarboxylic acid or a tetracarboxylic dianhydride. Examples of the tetracarboxylic acid residue include a residue obtained by eliminating four carboxyl groups from a tetracarboxylic acid, or a residue obtained by eliminating an acid dianhydride structure from a tetracarboxylic dianhydride. Examples of the tetracarboxylic acid residue include tetravalent tetracarboxylic acid residues having 2 to 40 carbon atoms.

The aliphatic diamine residue is not particularly limited as long as it is a divalent group derived from an aliphatic diamine compound. Examples of the aliphatic diamine residue include residues obtained by eliminating two amino groups from aliphatic diamine compounds. The aromatic diamine residue is not particularly limited as long as it is a divalent group derived from an aromatic diamine compound. Examples of the aromatic diamine residue include residues obtained by eliminating two amino groups from aromatic diamine compounds.

The hydrocarbon group is not particularly limited as long as it is a hydrocarbon group having 1 to 20 carbon atoms. The acid anhydride group is not particularly limited. Examples of the acid anhydride group include an acid anhydride group contained in a tetracarboxylic dianhydride (a raw material of the imide compound (B)) before the tetracarboxylic acid residue is formed.

As described above, the imide compound (B) is an imide compound having at least one of a hydrocarbon group or a maleimide group at the molecular end. In other words, the imide compound (B) is a compound having a structure represented by Formula (1) where X₄ and X₅ each independently represent a hydrocarbon group having 1 to 20 carbon atoms, a maleimide group, or an acid anhydride group and at least one of X₄ or X₅ represents a hydrocarbon group having 1 to 20 carbon atoms or a maleimide group. Examples of the imide compound (B) include an imide compound (B-1) that is the imide compound in which at least one of X₄ or X₅ is a hydrocarbon group having 1 to 20 carbon atoms, and an imide compound (B-2) that is the imide compound in which at least one of X₄ or X₅ is a maleimide group.

In the imide compound (B-1), m and n are average values of the number of repeating units (degree of polymerization), and examples of the sum of m and n include the number of repeating units that becomes the following acid value or weight average molecular weight. The sum of m and n is, for example, preferably 1 to 50. The ratio [m/(m+n)] of m to the sum of m and n is preferably 0 or more and 0.98 or less [0≤m/(m+n)≤0.98], more preferably 0 or more and 0.5 or less [0≤m/(m+n)≤0.5], still more preferably 0 or more and 0.4 or less [0≤m/(m+n)≤0.4]. The ratio [m/(m+n)] of m to the sum of m and n represents the proportion of the aliphatic amine residue in the sum of the aliphatic diamine residue and the aromatic diamine residue.

In the imide compound (B-2), m and n are average values of the number of repeating units (degree of polymerization), and examples of the sum of m and n include the number of repeating units that becomes the following acid value or weight average molecular weight. The sum of m and n is, for example, preferably 1 to 50, more preferably 1 to 15. The ratio [m/(m+n)] of m to the sum of m and n is preferably 0 or more and 0.98 or less [0≤m/(m+n)≤0.98], more preferably 0 or more and 0.5 or less [0≤m/(m+n)≤0.5], still more preferably 0 or more and 0.4 or less [0≤m/(m+n)≤0.4].

The acid value of the imide compound (B-1) is preferably 0 to 20 mgKOH/g, more preferably 0 to 15 mgKOH/g. When the acid value is too high, the compatibility with the maleimide compound (A) is improved, and the cured product obtained tends to have a low glass transition temperature and a high coefficient of thermal expansion.

Here, the acid value represents the acid value per 1 g of the imide compound (B-1). The acid value can be measured by potentiometric titration in conformity with DIN EN ISO 2114.

The weight average molecular weight of the imide compound (B-1) is preferably 10,000 to 30,000, more preferably 10,000 to 20,000. When the weight average molecular weight is too low, the resin viscosity decreases, and the resin flowing during press molding tends to be too large. When the weight average molecular weight is too high, the resin viscosity increases, and the resin flowing during press molding tends to be too small or the compatibility with the maleimide compound (A) tends to decrease. When the resin flowing is too small, for example, there is a risk that the circuit filling properties decrease. When the compatibility with the maleimide compound (A) is too low, the dispersion state in the cured product deteriorates, and there is a risk that the maleimide compound (A) and the imide compound (B-1) become ununiform. Hence, it is preferable that the weight average molecular weight of the imide compound (B-1) is within the above range from the viewpoint of moldability and compatibility.

The weight average molecular weight of the imide compound (B-2) is preferably 600 to 5,000, more preferably 1,000 to 4,000. When the weight average molecular weight is too low, the resin viscosity decreases, and the resin flowing during press molding tends to be too large. When the weight average molecular weight is too high, the resin viscosity increases, and the resin flowing during press molding tends to be too small or the compatibility with the maleimide compound (A) tends to decrease. When the resin flowing is too small, for example, there is a risk that the circuit filling properties decrease. When the compatibility with the maleimide compound (A) is too low, the dispersion state in the cured product deteriorates, and there is a risk that the maleimide compound (A) and the imide compound (B-2) become ununiform. Hence, it is preferable that the weight average molecular weight of the imide compound (B-2) is within the above range from the viewpoint of moldability and compatibility.

Here, the weight average molecular weight may be measured by a general molecular weight measurement method, and specific examples thereof include a value measured by gel permeation chromatography (GPC).

The imide compound (B) [the imide compound (B-1) and the imide compound (B-2)] preferably contains an imide group at 2 to 4 mmol/g. When the amount of the imide group is too small, the cured product obtained tends to have a low glass transition temperature and a low coefficient of thermal expansion. When the amount of the imide group is too large, the compatibility with the maleimide compound (A) decreases, and the maleimide compound (A) and imide compound (B) in the cured product tend to be ununiform. Hence, it is preferable that the amount of the imide group is within the above range from the viewpoint of obtaining a resin composition that can be formed into a uniform cured product and affords a cured product having a low coefficient of thermal expansion.

The imide compound (B) may include another imide compound as long as it includes an imide compound having the structure represented by Formula (1) in the molecule.

### (Radical Polymerizable Compound (C))

The radical polymerizable compound (C) is a compound that is different from the maleimide compound (A) and the imide compound (B), and is not particularly limited as long as it is a radical polymerizable compound having a benzene ring to which an alkenyl group is bonded in the molecule and a weight average molecular weight of 1,000 or less. Examples of the alkenyl group include an allyl group, a vinyl group, and a propenyl group. In other words, examples of the radical polymerizable compound (C) include a radical polymerizable compound having a benzene ring to which at least one selected from the group consisting of an allyl group, a vinyl group, and a propenyl group is bonded in the molecule and a weight average molecular weight of 1,000 or less. As described above, the radical polymerizable compound (C) is a compound that is different from the maleimide compound (A) and the imide compound (B). In other words, in the resin composition, the maleimide compound (A), the imide compound (B), and the radical polymerizable compound (C) are different from one another.

The weight average molecular weight of the radical polymerizable compound (C) is preferably 1,000 or less, more preferably 110 to 600. When the weight average molecular weight is too low, the cured product obtained tends to have a low glass transition temperature and a low coefficient of thermal expansion. When the weight average molecular weight is too high as well, the cured product obtained tends to have a low glass transition temperature and a low coefficient of thermal expansion. Here, the weight average molecular weight may be measured by a general molecular weight measurement method, and specific examples thereof include a value measured by gel permeation chromatography (GPC).

Examples of the radical polymerizable compound (C) include a benzoxazine compound (C-1) having a benzene ring to which an alkenyl group is bonded in the molecule and a hydrocarbon-based compound (C-2) having a benzene ring to which an alkenyl group is bonded in the molecule.

The oxazine compound (C-1) is not particularly limited as long as it is an oxazine compound having a benzene ring to which an alkenyl group is bonded in the molecule. Examples of the benzoxazine group include a benzoxazine group represented by the following Formula (5). Examples of the benzoxazine compound (C-1) include a benzoxazine compound (C-1-1) having a benzoxazine group represented by the following Formula (5) in the molecule.

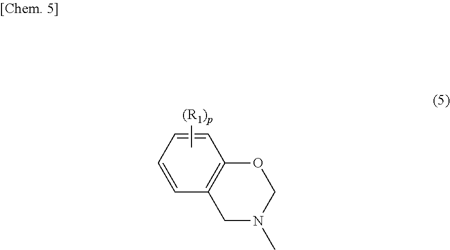

In Formula (5), R₁ represents an allyl group and p represents 1 to 4. p is the average value of the degree of substitution of R₁, and is 1 to 4, preferably 1.

Examples of the oxazine compound (C-1), specifically, the benzoxazine compound (C-1-1) include a benzoxazine compound (C-1-2) represented by the following Formula (6). As the benzoxazine compound (C-1), it is preferable to include the benzoxazine compound (C-1-2).

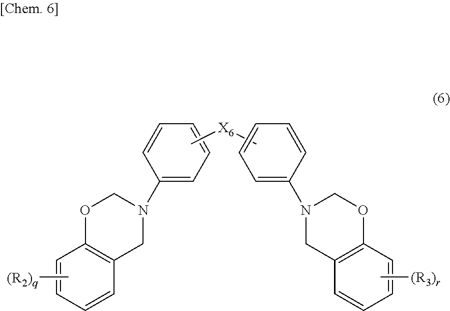

In Formula (6), R₂ and R₃ represent an allyl group, X₆ represents an alkylene group, and q and r each independently represent 1 to 4. In other words, q and r may be the same as or different from each other and each represent 1 to 4.

The alkylene group is not particularly limited, and examples thereof include a methylene group, an ethylene group, a propylene group, a butylene group, a pentylene group, a hexylene group, a heptylene group, an octane group, an icosane group, and a hexatriacontane group. Among these, a methylene group is preferable.

q is the average value of the degree of substitution of R₂, and is 1 to 4, preferably 1. r is the average value of the degree of substitution of R₃, and is 1 to 4, preferably 1.

The oxazine compound (C-1) may include an oxazine compound (another oxazine compound) other than the benzoxazine compound (C-1-1) (the benzoxazine compound (C-1-2) or the like) as long as it is an oxazine compound having an oxazine group in the molecule. Examples of the other oxazine compound include a benzoxazine compound (phenolphthalein-type benzoxazine compound) having a phenolphthalein structure in the molecule, a bisphenol F-type benzoxazine compound, and a diaminodiphenylmethane (DDM)-type benzoxazine compound. More specific examples of the other oxazine compound include 3,3′-(methylene-1,4-diphenylene)bis(3,4-dihydro-2H-1,3-benzoxazine) (P-d type benzoxazine compound) and a 2,2-bis(3,4-dihydro-2H-3-phenyl-1,3-benzoxazine)methane (F-a type benzoxazine compound).

As the benzoxazine compound (C-1), a commercially available product can be used, and for example, ALPd manufactured by SHIKOKU CHEMICALS CORPORATION or the like may be used.

As the benzoxazine compound (C-1), the benzoxazine compounds exemplified above may be used singly or in combination of two or more kinds thereof.

The hydrocarbon-based compound (C-2) is not particularly limited as long as it is a hydrocarbon-based compound having a benzene ring to which an alkenyl group is bonded in the molecule. Examples of the hydrocarbon-based compound (C-2) include divinylbenzenes such as o-divinylbenzene, m-divinylbenzene, and p-divinylbenzene; a hydrocarbon-based compound represented by the following Formula (7); and a hydrocarbon-based compound represented by the following Formula (9).

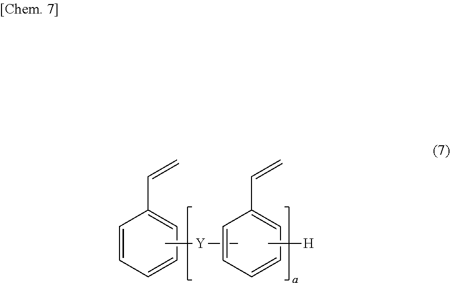

In Formula (7), Y represents a hydrocarbon group having 6 or more carbon atoms and containing at least one selected from an aromatic cyclic group or an aliphatic cyclic group. a represents 1 to 10.

The aromatic cyclic group is not particularly limited, but examples thereof include a phenylene group, a xylylene group, a naphthylene group, a tolylene group, and a biphenylene group. The aliphatic cyclic group is not particularly limited, but examples thereof include a group containing an indane structure and a group containing a cycloolefin structure. Among these, Y is preferably the aromatic cyclic group, more preferably a xylylene group. The number of carbon atoms in the hydrocarbon group is not particularly limited as long as it is 6 or more, but is preferably 6 to 20. More specific examples of the hydrocarbon-based compound (C-2) [hydrocarbon-based compound represented by Formula (7)] include a hydrocarbon-based compound represented by the following Formula (8). The hydrocarbon-based compound (C-2) preferably includes a hydrocarbon-based compound represented by the following Formula (8).

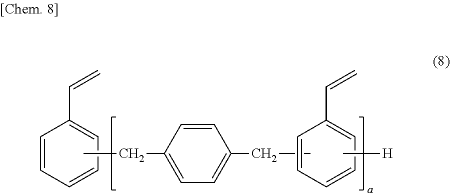

In Formula (8), a represents 1 to 10.

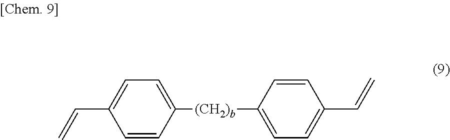

In Formula (9), b represents 0 to 20.

In the compound represented by Formula (9), b is 0 to 20, preferably 1 to 20, more preferably 1 to 12, still more preferably 1 to 6. Specific examples of the compound represented by Formula (9) include a compound represented by Formula (9) where b is 1 [bis(4-vinylphenyl)methane (BVPM)], a compound represented by Formula (9) where b is 2 [1,2-bis(vinylphenyl)ethane (BVPE)], and a compound represented by Formula (9) where b is 6 [1,6-bis(4-vinylphenyl)hexane (BVPH)].

As the radical polymerizable compound (C), the radical polymerizable compounds exemplified above may be used singly or in combination of two or more kinds thereof.

### (Inorganic Filler)

The resin composition may contain an inorganic filler, if necessary, as long as the effects of the present invention are not impaired. It is preferable to contain the inorganic filler from the viewpoint of enhancing the heat resistance and the like of the cured product of the resin composition. The inorganic filler is not particularly limited as long as it is an inorganic filler that can be used as an inorganic filler contained in a resin composition. Examples of the inorganic filler include metal oxides such as silica, alumina, titanium oxide, magnesium oxide and mica, metal hydroxides such as magnesium hydroxide and aluminum hydroxide, talc, aluminum borate, barium sulfate, aluminum nitride, boron nitride, barium titanate, strontium titanate, calcium titanate, aluminum titanate, magnesium carbonate such as anhydrous magnesium carbonate, and calcium carbonate. Among these, silica, metal hydroxides such as magnesium hydroxide and aluminum hydroxide, aluminum oxide, boron nitride, strontium titanate, calcium titanate, and the like are preferable, and silica is more preferable. The silica is not particularly limited, examples thereof include crushed silica, spherical silica, and silica particles, and spherical silica is preferable.

The inorganic filler may be an inorganic filler subjected to a surface treatment or an inorganic filler not subjected to a surface treatment. Examples of the surface treatment include treatment with a silane coupling agent.

The silane coupling agent is not particularly limited, and examples thereof include a silane coupling agent having at least one functional group selected from the group consisting of a vinyl group, a styryl group, a methacryloyl group, an acryloyl group, a phenylamino group, an isocyanurate group, a ureido group, a mercapto group, an isocyanate group, an epoxy group, and an acid anhydride group. In other words, examples of this silane coupling agent include compounds having at least one of a vinyl group, a styryl group, a methacryloyl group, an acryloyl group, a phenylamino group, an isocyanurate group, a ureido group, a mercapto group, an isocyanate group, an epoxy group, or an acid anhydride group as a reactive functional group, and further a hydrolyzable group such as a methoxy group or an ethoxy group.

Examples of the silane coupling agent include vinyltriethoxysilane and vinyltrimethoxysilane as those having a vinyl group. Examples of the silane coupling agent include p-styryltrimethoxysilane and p-styryltriethoxysilane as those having a styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as those having a methacryloyl group. Examples of the silane coupling agent include 3-acryloxypropyltrimethoxysilane and 3-acryloxypropyltriethoxysilane as those having an acryloyl group. Examples of the silane coupling agent include N-phenyl-3-aminopropyltrimethoxysilane and N-phenyl-3-aminopropyltriethoxysilane as those having a phenylamino group.

The average particle size of the inorganic filler is not particularly limited, and is preferably 0.05 to 10 μm, more preferably 0.1 to 8 μm. Here, the average particle size refers to the volume average particle size. The volume average particle size can be measured by, for example, a laser diffraction method and the like.

### (Content)

The content of the maleimide compound (A) is preferably 30 to 70 parts by mass, more preferably 35 to 65 parts by mass with respect to 100 parts by mass of the sum of the maleimide compound (A), the imide compound (B), and the radical polymerizable compound (C).

The content of the imide compound (B) is preferably 5 to 40 parts by mass, more preferably 10 to 35 parts by mass with respect to 100 parts by mass of the sum of the maleimide compound (A), the imide compound (B), and the radical polymerizable compound (C).

The content of the radical polymerizable compound (C) is preferably 5 to 40 parts by mass, more preferably 10 to 30 parts by mass with respect to 100 parts by mass of the sum of the maleimide compound (A), the imide compound (B), and the radical polymerizable compound (C).

When the contents of the maleimide compound (A), the imide compound (B), and the radical polymerizable compound (C) are within the above ranges, a resin composition that becomes a cured product, which has a low relative dielectric constant and a low dielectric loss tangent, sufficiently suppressed increases in relative dielectric constant and dielectric loss tangent due to water absorption, and a low coefficient of thermal expansion, is more suitably obtained. This is considered to be due to the fact that each of the effect exhibited by containing the maleimide compound (A), the effect exhibited by containing the imide compound (B), and the effect exhibited by containing the radical polymerizable compound (B) can be fully exerted when the contents of the maleimide compound (A), the imide compound (B), and the radical polymerizable compound (C) are within the above ranges.

### (Styrenic Polymer)

The resin composition may further contain a styrenic polymer. The styrenic polymer is, for example, a polymer obtained by polymerizing a monomer including a styrenic monomer, and may be a styrenic copolymer. Examples of the styrenic copolymer include a copolymer obtained by copolymerizing one or more styrenic monomers and one or more other monomers copolymerizable with the styrenic monomers. The styrenic copolymer may be a random copolymer or a block copolymer as long as a structure derived from the styrenic monomer is included in the molecule. Examples of the block copolymer include a binary copolymer of the structure (repeating unit) derived from the styrenic monomer and the other copolymerizable monomer (repeating unit), a ternary copolymer of the structure (repeating unit) derived from the styrenic monomer, the other copolymerizable monomer (repeating unit), and the structure (repeating unit) derived from the styrenic monomer, and a ternary copolymer of the structure (repeating unit) derived from the styrenic monomer, a randomly copolymerized block (repeating unit) containing the other copolymerizable monomer and the styrenic monomer, and a structure (repeating unit) derived from the styrenic monomer. The styrenic polymer may be a hydrogenated styrenic copolymer obtained by hydrogenating at least a part of the styrenic copolymer. More specific examples of the styrenic polymer include a methylstyrene (ethylene/butylene)methylstyrene block copolymer, a methylstyrene (ethylene-ethylene/propylene) methylstyrene block copolymer, a styrene-isoprene block copolymer, a hydrogenated styrene-isoprene-styrene block copolymer, a styrene (ethylene/butylene)-styrene block copolymer, a styrene (ethylene-ethylene/propylene) styrene block copolymer, a methylstyrene (styrene/butadiene randomly copolymerized block) methylstyrene copolymer, a styrene (styrene/butadiene randomly copolymerized block) styrene copolymer, and hydrogenated products obtained by hydrogenating at least a part of these.

(Organic component)

The resin composition according to the present embodiment may contain an organic component other than the maleimide compound (A), the imide compound (B), the radical polymerizable compound (C), and the styrenic polymer, if necessary, as long as the effects of the present invention are not impaired. Here, the organic component may or may not react with at least any one of the maleimide compound (A), the imide compound (B), or the radical polymerizable compound (C). Examples of the organic component include an epoxy compound, a methacrylate compound, an acrylate compound, a vinyl compound, a cyanate ester compound, an active ester compound, and an allyl compound.

The epoxy compound is a compound having an epoxy group in the molecule, and specific examples thereof include a bisphenol type epoxy compound such as a bisphenol A type epoxy compound, a phenol novolac type epoxy compound, a cresol novolac type epoxy compound, a dicyclopentadiene type epoxy compound, a bisphenol A novolac type epoxy compound, a biphenylaralkyl type epoxy compound, a polybutadiene compound having an epoxy group in the molecule, and a naphthalene ring-containing epoxy compound. The epoxy compound also includes an epoxy resin, which is a polymer of each of the epoxy compounds.

The methacrylate compound is a compound having a methacryloyl group in the molecule, and examples thereof include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include dimethacrylate compounds such as tricyclodecanedimethanol dimethacrylate (DCP).

The acrylate compound is a compound having an acryloyl group in the molecule, and examples thereof include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include diacrylate compounds such as tricyclodecanedimethanol diacrylate.

The vinyl compound is a compound having a vinyl group in the molecule, and examples thereof include a monofunctional vinyl compound (monovinyl compound) having one vinyl group in the molecule and a polyfunctional vinyl compound having two or more vinyl groups in the molecule. Examples of the polyfunctional vinyl compound include divinylbenzene, a curable polybutadiene having a carbon-carbon unsaturated double bond in the molecule, a butadiene-styrene copolymer other than the styrenic polymer, a polyphenylene ether compound having a vinylbenzyl group (ethenylbenzyl group) at the terminal, and modified polyphenylene ether obtained by modifying the terminal hydroxyl group of polyphenylene ether with a methacryl group. Examples of the butadiene-styrene copolymer other than the styrenic polymer include a curable butadiene-styrene copolymer having a carbon-carbon unsaturated double bond in the molecule and being liquid at 25° C., a curable butadiene-styrene random copolymer having a carbon-carbon unsaturated double bond in the molecule, and a curable butadiene-styrene random copolymer having a carbon-carbon unsaturated double bond in the molecule and being liquid at 25° C.

The cyanate ester compound is a compound having a cyanato group in the molecule, and examples thereof include 2,2-bis(4-cyanatophenyl)propane, bis(3,5-dimethyl-4-cyanatophenyl)methane, and 2,2-bis(4-cyanatophenyl)ethane.

The active ester compound is a compound having an ester group exhibiting high reaction activity in the molecule, and examples thereof include a benzenecarboxylic acid active ester, a benzenedicarboxylic acid active ester, a benzenetricarboxylic acid active ester, a benzenetetracarboxylic acid active ester, a naphthalenecarboxylic acid active ester, a naphthalenedicarboxylic acid active ester, a naphthalenetricarboxylic acid active ester, a naphthalenetetracarboxylic acid active ester, a fluorenecarboxylic acid active ester, a fluorenedicarboxylic acid active ester, a fluorenetricarboxylic acid active ester, and a fluorenetetracarboxylic acid active ester.

The allyl compound is a compound having an allyl group in the molecule, and examples thereof include a triallyl isocyanurate compound such as triallyl isocyanurate (TAIC), a diallyl bisphenol compound, and diallyl phthalate (DAP).

As the organic component, the organic components described above may be used singly or in combination of two or more kinds thereof.

The weight average molecular weight of the organic component is not particularly limited, and is, for example, preferably 100 to 5000, more preferably 100 to 4000, still more preferably 100 to 3000. When the weight average molecular weight of the organic component is too low, there is a risk that the organic component easily volatilizes from the blended component system of the resin composition. When the weight average molecular weight of the organic component is too high, the viscosity of the varnish of the resin composition and the melt viscosity at the time of heat molding become too high, and there is a risk of deterioration in appearance and moldability when the resin composition is brought into B stage. Hence, a resin composition imparting superior heat resistance and moldability to its cured product is obtained when the weight average molecular weight of the organic component is in such a range. It is considered that this is because the resin composition can be suitably cured. Here, the weight average molecular weight may be measured by a general molecular weight measurement method, and specific examples thereof include a value measured by gel permeation chromatography (GPC).

In the organic component, the average number (number of functional groups) of the functional groups, which contribute to the reaction during curing of the resin composition, per one molecule of the organic component varies depending on the weight average molecular weight of the organic component but is, for example, preferably 1 to 20, more preferably 2 to 18. When this number of functional groups is too small, sufficient heat resistance of the cured product tends to be hardly attained. When the number of functional groups is too large, the reactivity is too high and, for example, troubles such as a decrease in the storage stability of the resin composition or a decrease in the fluidity of the resin composition may occur.

### (Other Components)

The resin composition may contain components (other components) other than the maleimide compound (A), the imide compound (B), and the radical polymerizable compound (C) as long as the effects of the present invention are not impaired. As described above, the resin composition may contain the styrenic polymer, the inorganic filler, and the organic component as the other components. Examples of the other components other than the styrenic polymer, the inorganic filler, and the organic component include additives such as a flame retardant, a reaction initiator, a curing accelerator, a catalyst, a polymerization retarder, a polymerization inhibitor, a dispersant, a leveling agent, a coupling agent, an antifoaming agent, an antioxidant, a heat stabilizer, an antistatic agent, an ultraviolet absorber, a dye or a pigment, and a lubricant.

As described above, the resin composition according to the present embodiment may contain a flame retardant. The flame retardancy of a cured product of the resin composition can be enhanced by containing a flame retardant. The flame retardant is not particularly limited. Specifically, in the field in which halogen-based flame retardants such as bromine-based flame retardants are used, for example, ethylenedipentabromobenzene, ethylenebistetrabromoimide, decabromodiphenyloxide, and tetradecabromodiphenoxybenzene that have a melting point of 300° C. or more, and a bromostyrene-based compound that reacts with the polymerizable compound are preferable. It is considered that the elimination of halogen at a high temperature and the decrease in heat resistance can be suppressed by the use of a halogen-based flame retardant. There is a case where a flame retardant containing phosphorus (phosphorus-based flame retardant) is used in fields required to be halogen-free. The phosphorus-based flame retardant is not particularly limited, and examples thereof include a phosphate ester-based flame retardant, a phosphazene-based flame retardant, a bis(diphenylphosphine oxide)-based flame retardant, a 9,10-dihydro-9-oxa-10-phosphaphenanthrene-10-oxide (DOPO)-based flame retardant, and a phosphinate salt-based flame retardant. Specific examples of the phosphate ester-based flame retardant include a condensed phosphate ester such as dixylenyl phosphate. Specific examples of the phosphazene-based flame retardant include phenoxyphosphazene. Specific examples of the bis(diphenylphosphine oxide)-based flame retardant include xylylenebis(diphenylphosphine oxide). Specific examples of the DOPO-based flame retardant include hydrocarbons having two DOPO groups in the molecule (DOPO derivative compounds) and DOPO having a reactive functional group. Specific examples of the phosphinate-based flame retardant include metal phosphinates such as an aluminum dialkyl phosphinate. As the flame retardant, the respective flame retardants exemplified may be used singly or in combination of two or more kinds thereof.

As described above, the resin composition according to the present embodiment may contain a reaction initiator. The reaction initiator is not particularly limited as long as it can promote the curing reaction of the resin composition, and examples thereof include a peroxide and an organic azo compound. Examples of the peroxide include α,α′-di(t-butylperoxy)diisopropylbenzene (PBP), 2,5-dimethyl-2,5-di(t-butylperoxy)-3-hexyne, and benzoyl peroxide. Examples of the organic azo compound include azobisisobutyronitrile. A metal carboxylate can be concurrently used if necessary. By doing so, the curing reaction can be further promoted. Among these, α,α′-di(t-butylperoxy)diisopropylbenzene is preferably used. α,α′-Di(t-butylperoxy)diisopropylbenzene has a relatively high reaction initiation temperature and thus can suppress the promotion of the curing reaction at the time point at which curing is not required, for example, at the time of prepreg drying, and can suppress a decrease in storage stability of the resin composition. α,α′-Di(t-butylperoxy)diisopropylbenzene exhibits low volatility, and thus does not volatilize at the time of prepreg drying and storage, and exhibits favorable stability. The reaction initiators may be used singly or in combination of two or more kinds thereof.

As described above, the resin composition according to the present embodiment may contain a curing accelerator. The curing accelerator is not particularly limited as long as it can promote the curing reaction of the resin composition. Specific examples of the curing accelerator include imidazoles and derivatives thereof, organophosphorus compounds, amines such as secondary amines and tertiary amines, quaternary ammonium salts, organoboron compounds, and metal soaps. Examples of the imidazoles include 2-ethyl-4-methylimidazole (2E4MZ), 2-methylimidazole, 2-phenyl-4-methylimidazole, 2-phenylimidazole, and 1-benzyl-2-methylimidazole. Examples of the organophosphorus compounds include triphenylphosphine, diphenylphosphine, phenylphosphine, tributylphosphine, and trimethylphosphine. Examples of the amines include dimethylbenzylamine, triethylenediamine, triethanolamine, and 1,8-diaza-bicyclo(5,4,0)undecene-7 (DBU). Examples of the quaternary ammonium salts include tetrabutylammonium bromide. Examples of the organoboron compounds include tetraphenylboron salts such as 2-ethyl-4-methylimidazole-tetraphenylborate and tetra-substituted phosphonium/tetra-substituted borate such as tetraphenylphosphonium/ethyltriphenylborate. The metal soap refers to a fatty acid metal salt, and may be a linear fatty acid metal salt or a cyclic fatty acid metal salt. Specific examples of the metal soaps include linear aliphatic metal salts and cyclic aliphatic metal salts having 6 to 10 carbon atoms. More specific examples thereof include aliphatic metal salts formed from linear fatty acids such as stearic acid, lauric acid, ricinoleic acid, and octylic acid and cyclic fatty acids such as naphthenic acid and metals such as lithium, magnesium, calcium, barium, copper, and zinc. Examples thereof include zinc octylate. The curing accelerators may be used singly or in combination of two or more kinds thereof.

As described above, the resin composition according to the present embodiment may contain a silane coupling agent. The silane coupling agent may be contained in the resin composition or may be contained as a silane coupling agent covered on the inorganic filler contained in the resin composition for surface treatment in advance. Among them, it is preferable that the silane coupling agent is contained as a silane coupling agent covered on the inorganic filler for surface treatment in advance, and it is more preferable that the silane coupling agent is contained as a silane coupling agent covered on the inorganic filler for surface treatment in advance and further is also contained in the resin composition. In the case of a prepreg, the silane coupling agent may be contained in the prepreg as a silane coupling agent covered on the fibrous base material for surface treatment in advance. Examples of the silane coupling agent include those similar to the silane coupling agents used in the surface treatment of the inorganic filler described above.

The resin composition according to the present embodiment is a resin composition that affords a cured product, which has a low relative dielectric constant and a low dielectric loss tangent, sufficiently suppressed increases in relative dielectric constant and dielectric loss tangent due to water absorption, and a low coefficient of thermal expansion.

### (Use)

The resin composition is used when a prepreg is manufactured, as described later. The resin composition is used when a resin layer included in a metal foil with resin and a film with resin is formed and when an insulating layer included in a metal-clad laminate and a wiring board is formed.

### (Production Method)

The method for producing the resin composition is not particularly limited, and examples thereof include a method in which the maleimide compound (A), the imide compound (B), the radical polymerizable compound (C), and if necessary, components other than the maleimide compound (A), the imide compound (B), and the radical polymerizable compound (C), are mixed together so as to have predetermined contents. Examples thereof include the method to be described later in the case of obtaining a varnish-like composition containing an organic solvent.

By using the resin composition according to the present embodiment, a prepreg, a metal-clad laminate, a wiring board, a metal foil with resin, and a film with resin can be obtained as described below.

### [Prepreg]

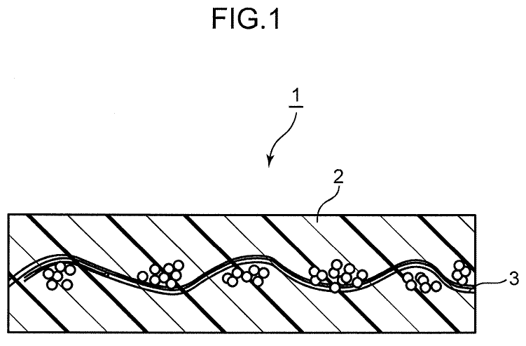

FIG. 1 is a schematic sectional view illustrating an example of a prepreg 1 according to an embodiment of the present invention.

As illustrated in FIG. 1, the prepreg 1 according to the present embodiment includes the resin composition or a semi-cured product 2 of the resin composition and a fibrous base material 3. This prepreg 1 includes the resin composition or the semi-cured product 2 of the resin composition and the fibrous base material 3 present in the resin composition or the semi-cured product 2 of the resin composition.

In the present embodiment, the semi-cured product is in a state in which the resin composition has been cured to an extent that the resin composition can be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, the semi-cured state includes a state where the viscosity has started to increase but curing is not completed, and the like.

The prepreg to be obtained using the resin composition according to the present embodiment may include a semi-cured product of the resin composition as described above or include the uncured resin composition itself. In other words, the prepreg may be a prepreg including a semi-cured product of the resin composition (the resin composition in B stage) and a fibrous base material or a prepreg including the resin composition before being cured (the resin composition in A stage) and a fibrous base material. The resin composition or a semi-cured product of the resin composition may be one obtained by drying or heating and drying the resin composition.

When a prepreg is manufactured, the resin composition 2 is often prepared in a varnish form and used in order to be impregnated into the fibrous base material 3 which is a base material for forming the prepreg. In other words, the resin composition 2 is usually a resin varnish prepared in a varnish form in many cases. Such a varnish-like resin composition (resin varnish) is prepared, for example, as follows.

First, the respective components which can be dissolved in an organic solvent are introduced into and dissolved in an organic solvent. At this time, heating may be performed if necessary. Thereafter, components which are used if necessary but are not dissolved in the organic solvent are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the maleimide compound (A), the imide compound (B), the radical polymerizable compound (C) and the like and does not inhibit the curing reaction. Specific examples thereof include toluene and methyl ethyl ketone (MEK).

Specific examples of the fibrous base material include glass cloth, aramid cloth, polyester cloth, a glass nonwoven fabric, an aramid nonwoven fabric, a polyester nonwoven fabric, pulp paper, and linter paper. When glass cloth is used, a laminate exhibiting excellent mechanical strength is obtained, and glass cloth subjected to flattening is particularly preferable. Specific examples of the flattening include a method in which glass cloth is continuously pressed at an appropriate pressure using a press roll to flatly compress the yarn. The thickness of the generally used fibrous base material is, for example, 0.01 mm or more and 0.3 mm or less. The glass fiber constituting the glass cloth is not particularly limited, and examples thereof include Q glass, NE glass, E glass, S glass, T glass, L glass, and L2 glass. The surface of the fibrous base material may be subjected to a surface treatment with a silane coupling agent. The silane coupling agent is not particularly limited, and examples thereof include a silane coupling agent having at least one selected from the group consisting of a vinyl group, an acryloyl group, a methacryloyl group, a styryl group, an amino group, and an epoxy group in the molecule.

The method for manufacturing the prepreg is not particularly limited as long as the prepreg can be manufactured. Specifically, when the prepreg is manufactured, the resin composition according to the present embodiment described above is often prepared in a varnish form and used as a resin varnish as described above.

Specific examples of the method for manufacturing the prepreg 1 include a method in which the fibrous base material 3 is impregnated with the resin composition 2, for example, the resin composition 2 prepared in a varnish form, and then dried. The fibrous base material 3 is impregnated with the resin composition 2 by dipping, coating, and the like. If necessary, the impregnation can be repeated a plurality of times. Moreover, at this time, it is also possible to finally adjust the composition and impregnated amount to the desired composition and impregnated amount by repeating impregnation using a plurality of resin compositions having different compositions and concentrations.

The fibrous base material 3 impregnated with the resin composition (resin varnish) 2 is heated under desired heating conditions, for example, at 40° C. or more and 180° C. or less for 1 minute or more and 10 minutes or less. By heating, the prepreg 1 before being cured (A-stage) or in a semi-cured state (B-stage) is obtained. By the heating, the organic solvent can be decreased or removed by being volatilized from the resin varnish.

The resin composition according to the present embodiment is a resin composition that becomes a cured product, which has a low relative dielectric constant and a low dielectric loss tangent, sufficiently suppressed increases in relative dielectric constant and dielectric loss tangent due to water absorption, and a low coefficient of thermal expansion. In other words, as being cured, the resin composition becomes a cured product, which has a low relative dielectric constant and a low dielectric loss tangent, sufficiently suppressed increases in relative dielectric constant and dielectric loss tangent due to water absorption, and a low coefficient of thermal expansion. For this reason, a prepreg including this resin composition or a semi-cured product of this resin composition is a prepreg that affords a cured product, which has a low relative dielectric constant and a low dielectric loss tangent, sufficiently suppressed increases in relative dielectric constant and dielectric loss tangent due to water absorption, and a low coefficient of thermal expansion. Specifically, the relative dielectric constant of a cured product of the prepreg is preferably 3.1 or less, more preferably 3 or less at a frequency of 10 GHz. The dielectric loss tangent of a cured product of the prepreg is preferably 0.004 or less, more preferably 0.0037 or less at a frequency of 10 GHz. The amount of change in relative dielectric constant when the cured product absorbs water (relative dielectric constant of the cured product after water absorption−relative dielectric constant of the cured product before water absorption) is preferably 0.2 or less, more preferably 0.18 or less. The amount of change in dielectric loss tangent when the cured product absorbs water (dielectric loss tangent of the cured product after water absorption−dielectric loss tangent of the cured product before water absorption) is preferably 0.013 or less, more preferably 0.011 or less. The relative dielectric constant and dielectric loss tangent here are the relative dielectric constant and dielectric loss tangent of a cured product of the prepreg at a frequency of 10 GHz, and examples thereof include the relative dielectric constant and dielectric loss tangent of a cured product of the prepreg at a frequency of 10 GHz measured by the cavity perturbation method. The coefficient of thermal expansion of a cured product of the prepreg is preferably 150 ppm/° C. or less, more preferably 110 ppm/° C. or less. For this reason, a prepreg including this resin composition or a semi-cured product of this resin composition is a prepreg that affords a cured product, which has a low relative dielectric constant and a low dielectric loss tangent, sufficiently suppressed increases in relative dielectric constant and dielectric loss tangent due to water absorption, and a low coefficient of thermal expansion. Hence, by using this prepreg, it is possible to suitably manufacture a wiring board including an insulating layer containing a cured product, which has a low relative dielectric constant and a low dielectric loss tangent, sufficiently suppressed increases in relative dielectric constant and dielectric loss tangent due to water absorption, and a low coefficient of thermal expansion.

### [Metal-Clad Laminate]

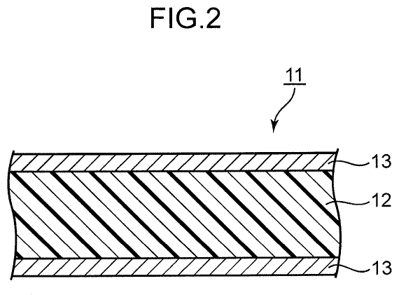

FIG. 2 is a schematic sectional view illustrating an example of a metal-clad laminate 11 according to an embodiment of the present invention.

As illustrated in FIG. 2, the metal-clad laminate 11 according to the present embodiment includes an insulating layer 12 containing a cured product of the resin composition and a metal foil 13 provided on the insulating layer 12. Examples of the metal-clad laminate 11 include a metal-clad laminate including an insulating layer 12 containing a cured product of the prepreg 1 illustrated in FIG. 1 and a metal foil 13 to be laminated together with the insulating layer 12. The insulating layer 12 may be formed of a cured product of the resin composition or a cured product of the prepreg. In addition, the thickness of the metal foil 13 varies depending on the performance and the like to be required for the finally obtained wiring board and is not particularly limited. The thickness of the metal foil 13 can be appropriately set depending on the desired purpose and is preferably, for example, 0.2 to 70 μm. Examples of the metal foil 13 include a copper foil and an aluminum foil, and the metal foil 13 may be a copper foil with carrier which includes a release layer and a carrier for the improvement in handleability in a case where the metal foil is thin.

The method for manufacturing the metal-clad laminate 11 is not particularly limited as long as the metal-clad laminate 11 can be manufactured. Specific examples thereof include a method in which the metal-clad laminate 11 is fabricated using the prepreg 1. Examples of this method include a method in which the double-sided metal foil-clad or single-sided metal foil-clad laminate 11 is fabricated by stacking one sheet or a plurality of sheets of prepreg 1, further stacking the metal foil 13 such as a copper foil on both or one of upper and lower surfaces of the prepregs 1, and laminating and integrating the metal foils 13 and prepregs 1 by heating and pressing. In other words, the metal-clad laminate 11 is obtained by laminating the metal foil 13 on the prepreg 1 and then performing heating and pressing. The heating and pressing conditions can be appropriately set depending on the thickness of the metal-clad laminate 11, the kind of the resin composition contained in the prepreg 1, and the like. For example, it is possible to set the temperature to 170 to 230° C., the pressure to 2 to 4 MPa, and the time to 60 to 150 minutes. Moreover, the metal-clad laminate may be manufactured without using a prepreg. Examples thereof include a method in which a varnish-like resin composition is applied on a metal foil to form a layer containing the resin composition on the metal foil and then heating and pressing is performed.

The resin composition according to the present embodiment is a resin composition that becomes a cured product, which has a low relative dielectric constant and a low dielectric loss tangent, sufficiently suppressed increases in relative dielectric constant and dielectric loss tangent due to water absorption, and a low coefficient of thermal expansion. In other words, as being cured, the resin composition becomes a cured product, which has a low relative dielectric constant and a low dielectric loss tangent, sufficiently suppressed increases in relative dielectric constant and dielectric loss tangent due to water absorption, and a low coefficient of thermal expansion. For this reason, a metal-clad laminate including an insulating layer containing a cured product of this resin composition is a metal-clad laminate including an insulating layer containing a cured product, which has a low relative dielectric constant and a low dielectric loss tangent, sufficiently suppressed increases in relative dielectric constant and dielectric loss tangent due to water absorption, and a low coefficient of thermal expansion. By using this metal-clad laminate, it is possible to suitably manufacture a wiring board including an insulating layer containing a cured product, which has a low relative dielectric constant and a low dielectric loss tangent, sufficiently suppressed increases in relative dielectric constant and dielectric loss tangent due to water absorption, and a low coefficient of thermal expansion.

### [Wiring Board]

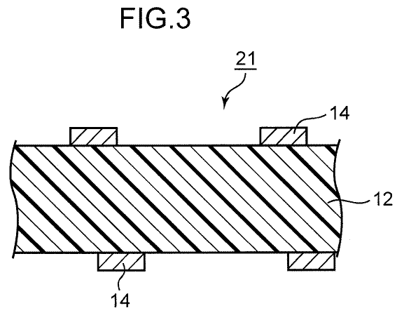

FIG. 3 is a schematic sectional view illustrating an example of a wiring board 21 according to an embodiment of the present invention.

As illustrated in FIG. 3, the wiring board 21 according to the present embodiment includes an insulating layer 12 containing a cured product of the resin composition and wiring 14 provided on the insulating layer 12. Examples of the wiring board 21 include a wiring board formed of an insulating layer 12 obtained by curing the prepreg 1 illustrated in FIG. 1 and wiring 14 which is laminated together with the insulating layer 12 and is formed by partially removing the metal foil 13. The insulating layer 12 may be formed of a cured product of the resin composition or a cured product of the prepreg.

The method for manufacturing the wiring board 21 is not particularly limited as long as the wiring board 21 can be manufactured. Specific examples thereof include a method in which the wiring board 21 is fabricated using the prepreg 1. Examples of this method include a method in which the wiring board 21, in which wiring is provided as a circuit on the surface of the insulating layer 12, is fabricated by forming wiring through etching and the like of the metal foil 13 on the surface of the metal-clad laminate 11 fabricated in the manner described above. In other words, the wiring board 21 is obtained by partially removing the metal foil 13 on the surface of the metal-clad laminate 11 and thus forming a circuit. Examples of the method for forming a circuit include circuit formation by a semi-additive process (SAP) or a modified semi-additive process (MSAP) in addition to the method described above.

The resin composition according to the present embodiment is a resin composition that becomes a cured product, which has a low relative dielectric constant and a low dielectric loss tangent, sufficiently suppressed increases in relative dielectric constant and dielectric loss tangent due to water absorption, and a low coefficient of thermal expansion. In other words, as being cured, the resin composition becomes a cured product, which has a low relative dielectric constant and a low dielectric loss tangent, sufficiently suppressed increases in relative dielectric constant and dielectric loss tangent due to water absorption, and a low coefficient of thermal expansion. For this reason, a wiring board including an insulating layer containing a cured product of this resin composition is a wiring board including an insulating layer containing a cured product, which has a low relative dielectric constant and a low dielectric loss tangent, sufficiently suppressed increases in relative dielectric constant and dielectric loss tangent due to water absorption, and a low coefficient of thermal expansion.

The metal-clad laminate and the wiring board include the insulating layer as described above. Specifically, the insulating layer (the insulating layer included in the metal-clad laminate and the insulating layer included in the wiring board) is preferably the following insulating layer. The relative dielectric constant of the insulating layer is preferably 3.1 or less, more preferably 3 or less at a frequency of 10 GHz. The dielectric loss tangent of the insulating layer is preferably 0.004 or less, more preferably 0.0037 or less at a frequency of 10 GHz. The amount of change in relative dielectric constant when the insulating layer absorbs water (relative dielectric constant of the insulating layer after water absorption−relative dielectric constant of the insulating layer before water absorption) is preferably 0.2 or less, more preferably 0.18 or less. The amount of change in dielectric loss tangent when the insulating layer absorbs water (dielectric loss tangent of the insulating layer after water absorption−dielectric loss tangent of the insulating layer before water absorption) is preferably 0.013 or less, more preferably 0.011 or less. The relative dielectric constant and dielectric loss tangent here are the relative dielectric constant and dielectric loss tangent of the insulating layer at a frequency of 10 GHz, and examples thereof include the relative dielectric constant and dielectric loss tangent of the insulating layer at a frequency of 10 GHz measured by the cavity perturbation method. The coefficient of thermal expansion of the insulating layer is preferably 150 ppm/° C. or less, more preferably 110 ppm/° C. or less.

[Metal Foil with Resin]

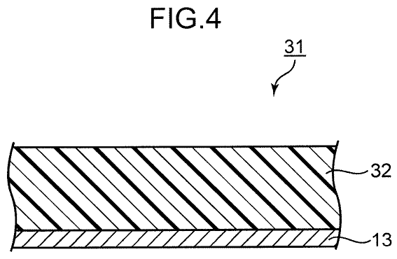

FIG. 4 is a schematic sectional view illustrating an example of a metal foil with resin 31 according to the present embodiment.

The metal foil with resin 31 according to the present embodiment includes a resin layer 32 containing the resin composition or a semi-cured product of the resin composition and a metal foil 13 as illustrated in FIG. 4. The metal foil with resin 31 includes the metal foil 13 on the surface of the resin layer 32. In other words, the metal foil with resin 31 includes the resin layer 32 and the metal foil 13 to be laminated together with the resin layer 32. The metal foil with resin 31 may include other layers between the resin layer 32 and the metal foil 13.

The resin layer 32 may contain a semi-cured product of the resin composition as described above or may contain the uncured resin composition. In other words, the metal foil with resin 31 may be a metal foil with resin including a resin layer containing a semi-cured product of the resin composition (the resin composition in B stage) and a metal foil or a metal foil with resin including a resin layer containing the resin composition before being cured (the resin composition in A stage) and a metal foil. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the metal foil, metal foils used in metal-clad laminates or metal foils with resin can be used without limitation. Examples of the metal foil include a copper foil and an aluminum foil.

The metal foil with resin 31 may include a cover film and the like if necessary. By including a cover film, it is possible to prevent entry of foreign matter and the like. The cover film is not particularly limited, and examples thereof include a polyolefin film, a polyester film, a polymethylpentene film, and films formed by providing a release agent layer on these films.

The method for manufacturing the metal foil with resin 31 is not particularly limited as long as the metal foil with resin 31 can be manufactured. Examples of the method for manufacturing the metal foil with resin 31 include a method in which the varnish-like resin composition (resin varnish) is applied on the metal foil 13 and heated to manufacture the metal foil with resin 31. The varnish-like resin composition is applied on the metal foil 13 using, for example, a bar coater. The applied resin composition is heated under the conditions of, for example, 40° C. or more and 180° C. or less and 0.1 minute or more and 10 minutes or less. The heated resin composition is formed as the uncured resin layer 32 on the metal foil 13. By the heating, the organic solvent can be decreased or removed by being volatilized from the resin varnish.

The resin composition according to the present embodiment is a resin composition that becomes a cured product, which has a low relative dielectric constant and a low dielectric loss tangent, sufficiently suppressed increases in relative dielectric constant and dielectric loss tangent due to water absorption, and a low coefficient of thermal expansion. In other words, as being cured, the resin composition becomes a cured product, which has a low relative dielectric constant and a low dielectric loss tangent, sufficiently suppressed increases in relative dielectric constant and dielectric loss tangent due to water absorption, and a low coefficient of thermal expansion. For this reason, a metal foil with resin including a resin layer containing this resin composition or a semi-cured product of this resin composition is a metal foil with resin including a resin layer that affords an insulating layer containing a cured product, which has a low relative dielectric constant and a low dielectric loss tangent, sufficiently suppressed increases in relative dielectric constant and dielectric loss tangent due to water absorption, and a low coefficient of thermal expansion. This metal foil with resin can be used when a wiring board including a cured product, which has a low relative dielectric constant and a low dielectric loss tangent, sufficiently suppressed increases in relative dielectric constant and dielectric loss tangent due to water absorption, and a low coefficient of thermal expansion, is manufactured. For example, by laminating the metal foil with resin on a wiring board, a multilayer wiring board can be manufactured. As a wiring board obtained using such a metal foil with resin, there is obtained a wiring board including an insulating layer containing a cured product, which has a low relative dielectric constant and a low dielectric loss tangent, sufficiently suppressed increases in relative dielectric constant and dielectric loss tangent due to water absorption, and a low coefficient of thermal expansion.

[Film with Resin]

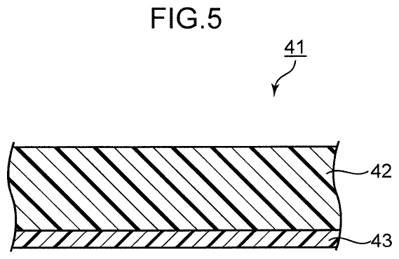

FIG. 5 is a schematic sectional view illustrating an example of a film with resin 41 according to the present embodiment.

The film with resin 41 according to the present embodiment includes a resin layer 42 containing the resin composition or a semi-cured product of the resin composition and a support film 43 as illustrated in FIG. 5. The film with resin 41 includes the resin layer 42 and the support film 43 to be laminated together with the resin layer 42. The film with resin 41 may include other layers between the resin layer 42 and the support film 43.

The resin layer 42 may contain a semi-cured product of the resin composition as described above or may contain the uncured resin composition. In other words, the film with resin 41 may be a film with resin including a resin layer containing a semi-cured product of the resin composition (the resin composition in B stage) and a support film or a film with resin including a resin layer containing the resin composition before being cured (the resin composition in A stage) and a support film. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the support film 43, support films used in films with resin can be used without limitation. Examples of the support film include electrically insulating films such as a polyester film, a polyethylene terephthalate (PET) film, a polyimide film, a polyparabanic acid film, a polyether ether ketone film, a polyphenylene sulfide film, a polyamide film, a polycarbonate film, and a polyarylate film.

The film with resin 41 may include a cover film and the like if necessary. By including a cover film, it is possible to prevent entry of foreign matter and the like. The cover film is not particularly limited, and examples thereof include a polyolefin film, a polyester film, and a polymethylpentene film.

The support film and the cover film may be those subjected to surface treatments such as a matt treatment, a corona treatment, a release treatment, and a roughening treatment if necessary.

The method for manufacturing the film with resin 41 is not particularly limited as long as the film with resin 41 can be manufactured. Examples of the method for manufacturing the film with resin 41 include a method in which the varnish-like resin composition (resin varnish) is applied on the support film 43 and heated to manufacture the film with resin 41. The varnish-like resin composition is applied on the support film 43 using, for example, a bar coater. The applied resin composition is heated under the conditions of, for example, 40° C. or more and 180° C. or less and 0.1 minute or more and 10 minutes or less. The heated resin composition is formed as the uncured resin layer 42 on the support film 43. By the heating, the organic solvent can be decreased or removed by being volatilized from the resin varnish.

The resin composition according to the present embodiment is a resin composition that affords a cured product, which has a low relative dielectric constant and a low dielectric loss tangent, sufficiently suppressed increases in relative dielectric constant and dielectric loss tangent due to water absorption, and a low coefficient of thermal expansion. In other words, as being cured, the resin composition becomes a cured product, which has a low relative dielectric constant and a low dielectric loss tangent, sufficiently suppressed increases in relative dielectric constant and dielectric loss tangent due to water absorption, and a low coefficient of thermal expansion. For this reason, a film with resin including a resin layer containing this resin composition or a semi-cured product of this resin composition is a film with resin including a resin layer that affords an insulating layer containing a cured product, which has a low relative dielectric constant and a low dielectric loss tangent, sufficiently suppressed increases in relative dielectric constant and dielectric loss tangent due to water absorption, and a low coefficient of thermal expansion. This film with resin can be used when a wiring board including an insulating layer containing a cured product, which has a low relative dielectric constant and a low dielectric loss tangent, sufficiently suppressed increases in relative dielectric constant and dielectric loss tangent due to water absorption, and a low coefficient of thermal expansion, is suitably manufactured. A multilayer wiring board can be manufactured, for example, by laminating the film with resin on a wiring board and then peeling off the support film from the film with resin or by peeling off the support film from the film with resin and then laminating the film with resin on a wiring board. As a wiring board obtained using such a film with resin, there is obtained a wiring board including an insulating layer containing a cured product, which has a low relative dielectric constant and a low dielectric loss tangent, sufficiently suppressed increases in relative dielectric constant and dielectric loss tangent due to water absorption, and a low coefficient of thermal expansion.

This specification discloses techniques in various aspects as described above, and the main techniques among these are summarized below.

A resin composition according to a first aspect is a resin composition containing a maleimide compound (A) having a benzene ring in the molecule and a maleimide equivalent of 500 g/mol or less; an imide compound (B) having at least one of a hydrocarbon group or a maleimide group at the molecular end; and a radical polymerizable compound (C) having a benzene ring to which an alkenyl group is bonded in the molecule and a weight average molecular weight of 1,000 or less.

A resin composition according to a second aspect is the resin composition according to the first aspect, in which the imide compound (B) has a structure represented by the following Formula (1) in a molecule.

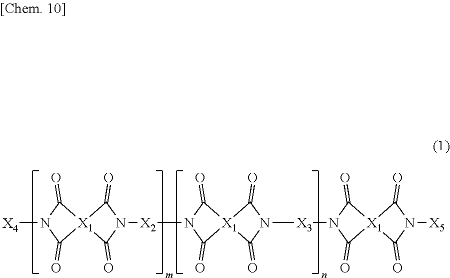

In Formula (1), X₁ represents a tetravalent tetracarboxylic acid residue, X₂ represents a divalent aliphatic diamine residue, X₃ represents a divalent aromatic diamine residue, X₄ and X₅ each independently represent a hydrocarbon group having 1 to 20 carbon atoms, a maleimide group, or an acid anhydride group, at least one of X₄ or X₅ represents a hydrocarbon group having 1 to 20 carbon atoms or a maleimide group, m represents 1 to 50, n represents 0 to 49, and a sum of m and n represents 1 to 50.

A resin composition according to a third aspect is the resin composition according to the first or second aspect, in which a weight average molecular weight of the imide compound (B) is 10,000 to 30,000.

A resin composition according to a fourth aspect is the resin composition according to any one of the first to third aspects, in which the maleimide compound (A) includes a maleimide compound having an arylene structure bonded in meta-orientation in a molecule.

A resin composition according to a fifth aspect is the resin composition according to any one of the first to fourth aspects, in which the alkenyl group in the radical polymerizable compound (C) includes at least one selected from the group consisting of an allyl group, a vinyl group, and a propenyl group.

A resin composition according to a sixth aspect is the resin composition according to any one of the first to fifth aspects, in which a content of the maleimide compound (A) is 30 to 70 parts by mass with respect to 100 parts by mass of a sum of the maleimide compound (A), the imide compound (B), and the radical polymerizable compound (C).

A resin composition according to a seventh aspect is the resin composition according to any one of the first to sixth aspects, in which a content of the imide compound (B) is 10 to 40 parts by mass with respect to 100 parts by mass of a sum of the maleimide compound (A), the imide compound (B), and the radical polymerizable compound (C).

A resin composition according to an eighth aspect is the resin composition according to any one of the first to seventh aspects, further containing an inorganic filler.

A prepreg according to a ninth aspect is a prepreg including the resin composition according to any one of the first to eighth aspects or a semi-cured product of the resin composition; and a fibrous base material.

A film with resin according to a tenth aspect is a film with resin including a resin layer containing the resin composition according to any one of the first to eighth aspects or a semi-cured product of the resin composition; and a support film.

A metal foil with resin according to an eleventh aspect is a metal foil with resin including a resin layer containing the resin composition according to any one of the first to eighth aspects or a semi-cured product of the resin composition; and a metal foil.

A metal-clad laminate according to a twelfth aspect is a metal-clad laminate including an insulating layer containing a cured product of the resin composition according to any one of the first to eighth aspects; and a metal foil.

A metal-clad laminate according to a thirteenth aspect is a metal-clad laminate including an insulating layer containing a cured product of the prepreg according to the ninth aspect; and a metal foil.

A wiring board according to a fourteenth aspect is a wiring board including an insulating layer containing a cured product of the resin composition according to any one of the first to eighth aspects; and a wiring.

A wiring board according to a fifteenth aspect is a wiring board including an insulating layer containing a cured product of the prepreg according to the ninth aspect; and a wiring.

According to the present invention, it is possible to provide a resin composition that affords a cured product, which has a low relative dielectric constant and a low dielectric loss tangent, sufficiently suppressed increases in relative dielectric constant and dielectric loss tangent due to water absorption, and a low coefficient of thermal expansion. Furthermore, according to the present invention, it is possible to provide a prepreg, a film with resin, a metal foil with resin, a metal-clad laminate, and a wiring board each obtained using the resin composition.

Hereinafter, the present invention will be described more specifically with reference to examples, but the scope of the present invention is not limited thereto.

### EXAMPLES

### Examples 1 to 12 and Comparative Examples 1 and 2

The respective components to be used when preparing a resin composition in the present examples will be described.

### (Maleimide Compound)

Maleimide compound: Maleimide compound having arylene structure bonded in meta-orientation in molecule (maleimide compound represented by Formula (4), solid component in MIR-5000-60T (maleimide compound dissolved in toluene) manufactured by Nippon Kayaku Co., Ltd.)

### (Imide Compound)

Imide compound-1: Imide compound having structure represented by Formula (1), where X₄ and X₅ are hydrocarbon group, in molecule (VA-9601 manufactured by TOYOCHEM CO., LTD., acid value: 1.0 mgKOH/g, weight average molecular weight: 24,000) Imide compound-2: Imide compound having structure represented by Formula (1), where X₄ and X₅ are hydrocarbon group, in molecule (VA-9603 manufactured by TOYOCHEM CO., LTD., acid value: 3.4 mgKOH/g, weight average molecular weight: 12,000) Imide compound-3: Imide compound having structure represented by Formula (1), where X₄ and X₅ are hydrocarbon group, in molecule (VA-9604 manufactured by TOYOCIEM CO., LTD., acid value: 0.6 mgKOH/g, weight average molecular weight: 11,000) Imide compound-4: Imide compound having maleimide group at molecular end (maleimide compound represented by the following Formula (10), BMI-3000J manufactured by Desingner Molercules Inc.)

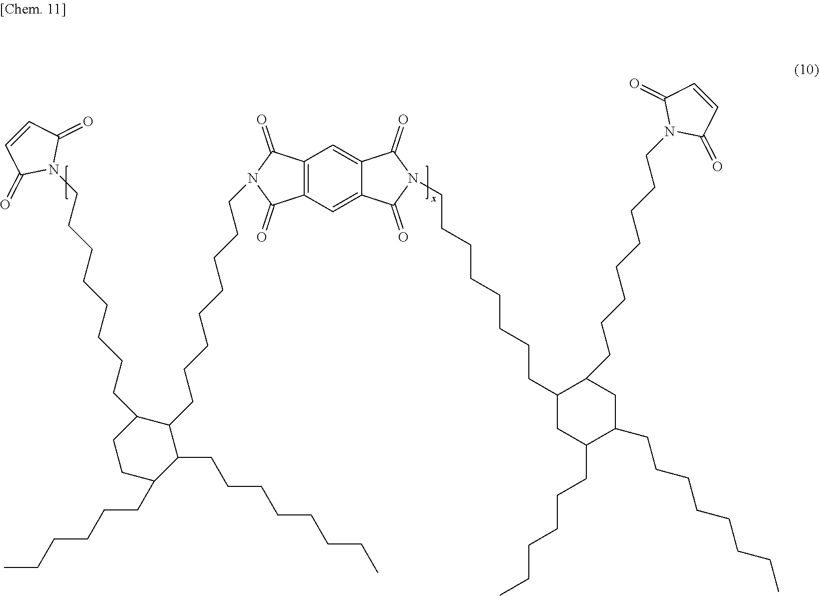

In Formula (10), x, which is a repeating unit, represents 1 to 10.

Imide compound-5: Imide compound having maleimide group at molecular end (maleimide compound represented by the following Formula (11), BMI-1500 manufactured by Desingner Molercules Inc.)

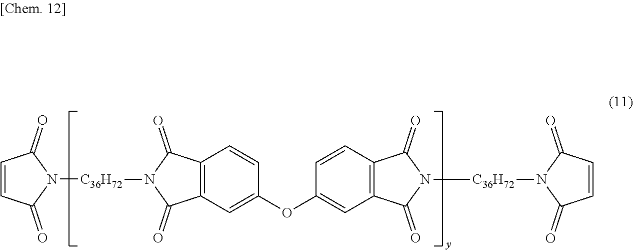

In Formula (11), y, which is a repeating unit, represents 1 to 10.

### (Radical Polymerizable Compound)

Benzoxazine compound: Benzoxazine compound having allyl group in molecule (benzoxazine compound represented by Formula (6), where X₆ is methylene group and q and r are 1, ALPd manufactured by SHIKOKU CHEMICALS CORPORATION)

Hydrocarbon-based compound-1: Hydrocarbon-based compound represented by Formula (8).

Specifically, the hydrocarbon-based compound-1 is a hydrocarbon-based compound synthesized as follows.

### Synthesis Example 1

Into a flask equipped with a thermometer, a condenser, and a stirrer, 296 parts by mass of 2-bromoethylbenzene (manufactured by Tokyo Chemical Industry Co., Ltd.), 70 parts by mass of α,α′-dichloro-p-xylene (manufactured by Tokyo Chemical Industry Co., Ltd.), and 18.4 parts by mass of methanesulfonic acid (manufactured by Tokyo Chemical Industry Co., Ltd.) were introduced, and the reaction was conducted at 130° C. for 8 hours. After the reaction, cooling was performed, then the reaction mixture obtained by the reaction was neutralized with an aqueous sodium hydroxide solution and extracted with 1200 parts by mass of toluene, and the organic layer was washed five times with 100 parts by mass of water. The solvent and excess 2-bromoethylbenzene were distilled off under heating and reduced pressure to obtain 160 parts by mass of an olefin compound precursor (BEB-1) having a 2-bromoethylbenzene structure as a liquid resin (Mn: 538, Mw: 649). A GPC chart of the obtained compound was determined, and the repeating unit n calculated from the area % in the acquired GPC chart was found to be 1.7. The ¹H-NMR chart (DMSO-d₆) of the obtained compound was determined, and signals attributed to the bromoethyl group were observed at 2.95 to 3.15 ppm and 3.60 to 3.75 ppm in the acquired ¹H-NMR chart.

### Synthesis Example 2

Next, 22 parts by mass of BEB-1 obtained in Synthesis Example 1, 50 parts by mass of toluene, 150 parts by mass of dimethyl sulfoxide, 15 parts by mass of water and 5.4 parts by mass of sodium hydroxide were introduced into a flask equipped with a thermometer, a condenser, and a stirrer, and the reaction was conducted at 40° C. for 5 hours. After the reaction, cooling was performed, then 100 parts by mass of toluene was added, and the organic layer was washed five times with 100 parts by mass of water. The solvent was distilled off under heating and reduced pressure to obtain 13 parts by mass of a liquid olefin compound having a styrene structure as a functional group (Mn: 432, Mw: 575). A GPC chart of the obtained compound was determined, and the repeating unit n calculated from the area % in the acquired GPC chart was found to be 1.7. The ¹H-NMR chart (DMSO-d₆) of the obtained compound was determined, and signals attributed to the vinyl group were observed at 5.10 to 5.30 ppm, 5.50 to 5.85 ppm, and 6.60 to 6.80 ppm in the acquired H-NMR chart.

The obtained compound (liquid olefin compound) was the hydrocarbon-based compound represented by Formula (8).

The weight average molecular weight (Mw) and number average molecular weight (Mn) used in Synthesis Example 1 and Synthesis Example 2 were values determined by the following analysis method.

### Analysis Method

The molecular weights were calculated in terms of polystyrene using a polystyrene standard solution.

GPC: DGU-20A3R, LC-20AD, SIL-20AIIT, RID-20A, SPD-20A, CTO-2, and CBM-20A (all manufactured by Shimadzu Corporation)
Column: Shodex KF-603, KF-602x2, KF-601x2)
Coupled eluent: Tetrahydrofuran
Flow velocity: 0.5 ml/min.
Column temperature: 40° C.
Detection: RI (differential refraction detector)
Hydrocarbon-based compound-2: 1,2-Bis(vinylphenyl)ethane (BVPE) (compound represented by Formula (9), where b is 2). Specifically, the hydrocarbon-based compound-2 is BVPE produced by subjecting vinylbenzyl chloride such as 1-(chloromethyl)-4-vinylbenzene to Grignard reaction.

Specifically, the hydrocarbon-based compound-2 was produced as follows.

First, 5.36 g (220 mmol) of granular magnesium for Grignard reaction (manufactured by KANTO CHEMICAL CO., INC.) was placed in a 500 ml three-necked flask, and a dropping funnel, a nitrogen inlet tube, and a septum cap were attached to the flask.

In the three-necked flask, the entire system was desiccated by heating using a dryer while stirring the granular magnesium using a stirrer under a nitrogen stream. After that, 300 ml of dry tetrahydrofuran was taken using a syringe and injected into the three-necked flask through the septum cap.

After the solution in the three-necked flask was cooled to −5° C., 30.5 g (200 mmol) of vinylbenzyl chloride (manufactured by TOKYO CHEMICAL INDUSTRY CO., LTD.) was added dropwise to the solution over about 4 hours using a dropping funnel. After termination of the dropwise addition, stirring was continuously performed at 0° C. for 20 hours to conduct the reaction of vinylbenzyl chloride. After termination of the reaction, the solution obtained by the reaction was filtered to remove residual magnesium and concentrated using an evaporator. This concentrated solution was diluted with hexane, washed one time with a 3.6% hydrochloric acid aqueous solution and three times with pure water, and then desiccated over magnesium sulfate. This desiccated solution was allowed to pass through a short column of silica gel (Wako Gel C300 manufactured by FUJIFILM Wako Pure Chemical Corporation)/hexane for purification, and vacuum dried to obtain BVPE.

Modified PPE: Polyphenylene ether compound having vinylbenzyl group (ethenylbenzyl group) at molecular end (styrene-modified polyphenylene ether) (OPE-2st 1200 manufactured by Mitsubishi Gas Chemical Company, Inc.)

### (Reaction Initiator)

PBP: α,α′-Di(t-butylperoxy)diisopropylbenzene (Perbutyl P (PBP) manufactured by NOF CORPORATION)

### (Curing Accelerator)

2E4MZ: 2-Ethyl-4-methylimidazole (2E4MZ manufactured by SHIKOKU CHEMICALS CORPORATION)

### (Inorganic Filler)

Silica: K180SV-C2 manufactured by ADMATECHS COMPANY LIMITED

### Preparation Method

First, the respective components other than the inorganic filler were added to and mixed in toluene, methyl ethyl ketone, or a mixed solvent of toluene and methyl ethyl ketone at the compositions (parts by mass) presented in Tables 1 and 2 so that the solid concentration was 40% to 60% by mass. The mixture was stirred for 60 minutes. Thereafter, in a case where an inorganic filler was contained, the inorganic filler was added to the obtained liquid, and dispersed using a bead mill. By doing so, a varnish-like resin composition (varnish) was obtained.

Next, a glass cloth (#1067 type, NE glass manufactured by Nitto Boseki Co., Ltd.) was impregnated with the obtained varnish, and then heated and dried at 100° C. to 160° C. for about 2 to 8 minutes to obtain a prepreg. At that time, the thickness of the prepreg after curing was adjusted to be about 76 μm (the content percentage of organic components in the resin composition was about 71% to 74% by mass).

### (Evaluation Substrate 1)

Then, four sheets of each of the obtained prepregs were stacked, a metal foil (MT18FL 1.5 manufactured by Mitsui Mining & Smelting Co., Ltd., a 1.5 μm thick copper foil with a 18 μm thick carrier foil) was disposed on both sides thereof to obtain a body to be pressed, and the body to be pressed was heated and pressed at a temperature of 220° C. and a pressure of 2 MPa for 2 hours, thereby obtaining a copper foil-clad laminate (metal-clad laminate) having a thickness of about 0.3 mm and copper foil pasted to both surfaces. This obtained copper foil-clad laminate was designated as an evaluation substrate 1.

### (Evaluation Substrate 2)

A copper-clad laminate (metal-clad laminate) having a thickness of about 1 mm was obtained by the same method as that for fabricating the evaluation substrate 1 except that the number of sheets of prepreg stacked was changed from 4 to 14. This obtained copper foil-clad laminate was designated as an evaluation substrate 2.

The evaluation substrate (metal-clad laminate) fabricated as described above was evaluated by the following methods.

### [Dielectric Properties (Relative Dielectric Constant and Dielectric Loss Tangent)]

The copper foil was removed from the evaluation substrate 1 (metal-clad laminate) by etching. The substrate thus obtained was used as a test piece, and the relative dielectric constant and dielectric loss tangent at 10 GHz were measured by the cavity perturbation method. Specifically, the relative dielectric constant (Dk) and dielectric loss tangent (Df) of the test piece at 10 GHz were measured using a network analyzer (N5230A manufactured by Agilent Technologies, Inc.). The relative dielectric constant and dielectric loss tangent were measured both before and after water absorption.

The difference between the relative dielectric constant of the test piece after water absorption and the relative dielectric constant of the test piece before water absorption was calculated. The difference between the dielectric loss tangent of the test piece after water absorption and the dielectric loss tangent of the test piece before water absorption was calculated.

When the relative dielectric constant (relative dielectric constant of the test piece before water absorption) acquired through measurement was 3.1 or less, it was judged to be “pass.” When the dielectric loss tangent (dielectric loss tangent of the test piece before water absorption) acquired through measurement was 0.004 or less, it was judged to be “pass.” When the amount of change in relative dielectric constant when the test piece absorbed water (relative dielectric constant of the test piece after water absorption−relative dielectric constant of the test piece before water absorption) was 0.2 or less, it was judged to be “pass.” When the amount of change in dielectric loss tangent when the test piece absorbed water (dielectric loss tangent of the test piece after water absorption−dielectric loss tangent of the test piece before water absorption) was 0.013 or less, it was judged to be “pass.”

### [Coefficient of Thermal Expansion]

Using an unclad substrate obtained by removing the copper foil from the evaluation substrate 2 (metal-clad laminate) by etching as a test piece, the coefficient of thermal expansion (CTE: ppm/° C.) in the Z-axis direction was measured by TMA (thermo-mechanical analysis). A TMA instrument (TMA7100 manufactured by Hitachi High-Tech Science Corporation) was used for the measurement, and the measurement was performed in the range of 50° C. to 260° C. when the test piece was heated from room temperature to 265° C. at a rate of temperature increase of 20° C./min, cooled to room temperature, and then heated at a rate of temperature increase of 10° C./min.

### [Dispersion State]

The entire surface of the evaluation substrate 1 (metal-clad laminate) was covered with an embedding resin. The evaluation substrate covered with the embedding resin was polished so that the cross section of the evaluation substrate was exposed. The cross section of the evaluation substrate exposed on the surface obtained by polishing was observed using a tabletop microscope (TM4000plus manufactured by Hitachi High-Tech Corporation) at an acceleration voltage of 5 to 15 kV and a magnification of 1000-fold.

In the case where an inorganic filler was contained, when the largest area among areas where the presence of the inorganic filler could not be found was 10 μm² or more, it was evaluated as “unevenly distributed”. When the largest area among areas where the presence of the inorganic filler could not be found was less than 10 μm² and when the areas (areas where the presence of the inorganic filler could not be found and areas where the presence of the inorganic filler could be found) could not be distinguished from each other, it was evaluated as “uniform.”

In the case where an inorganic filler was not contained, when the largest area among areas where the presence of uneven density of the resin could be found was 10 μm² or more, it was evaluated as “unevenly distributed”. When the largest area among areas where the presence of uneven density of the resin could be found was less than 10 μm² and when the areas (areas where the presence of uneven density of the resin could be found and areas where the presence of uneven density of the resin could not be found) could not be distinguished from each other, it was evaluated as “uniform.”

The results of the respective evaluations are presented in Tables 1 and 2.

TABLE 1

| | | | Examples | | | | | | | Comparative Example | |
|---|---|---|---|---|---|---|---|---|---|---|---|
| | | | 1 | 2 | 3 | 4 | 5 | 6 | 7 | 1 | 2 |
| Compo- | Maleimide compound | | 56 | 56 | 56 | 56 | 49 | 49 | 56 | 60 | 70 |
| sition | Imide | Imide | 20 | — | 20 | — | 30 | — | — | 20 | — |
| (parts | compound | compound-1 | | | | | | | | | |
| by mass) | | Imide | — | 20 | — | 20 | — | 30 | 30 | — | — |
| | | compound-2 | | | | | | | | | |
| | Radical | Benzoxazine | 24 | 24 | 24 | 24 | 21 | 21 | 14 | — | 30 |
| | polymer- | compound | | | | | | | | | |
| | izable | Modified | — | — | — | — | — | — | — | 20 | — |
| | compound | PPE | | | | | | | | | |
| | Reaction | PBP | 1 | 1 | 1 | 1 | 1 | 1 | 1 | 1 | 1 |
| | initiator | | | | | | | | | | |
| | Curing | 2E4MZ | 1 | 1 | 1 | 1 | 1 | 1 | 1 | — | 1 |
| | accelerator | | | | | | | | | | |
| | Inorganic | Silica | — | — | 40 | 40 | 40 | 40 | 40 | 40 | — |
| | filler | | | | | | | | | | |
| Evaluation | Before | Relative | 2.88 | 2.89 | 2.99 | 3.01 | 2.98 | 2.97 | 2.90 | 2.97 | 3.00 |
| | water | dielectric | | | | | | | | | |
| | absorption | constant | | | | | | | | | |
| | | Dielectric | 0.0037 | 0.0039 | 0.0039 | 0.0039 | 0.0036 | 0.0036 | 0.0031 | 0.0026 | 0.0047 |
| | | loss | | | | | | | | | |
| | | tangent | | | | | | | | | |
| | After | Relative | 3.07 | 3.08 | 3.17 | 3.19 | 3.13 | 3.12 | 3.08 | 3.09 | 3.28 |
| | water | dielectric | | | | | | | | | |
| | absorption | constant | | | | | | | | | |
| | | Dielectric | 0.0161 | 0.0150 | 0.0146 | 0.0149 | 0.0119 | 0.0119 | 0.0120 | 0.0100 | 0.0221 |
| | | loss | | | | | | | | | |
| | | tangent | | | | | | | | | |

| | | | | | | | | | |
|---|---|---|---|---|---|---|---|---|---|
| Amount of change in relative | 0.19 | 0.19 | 0.18 | 0.18 | 0.15 | 0.15 | 0.18 | 0.12 | 0.28 |
| dielectric constant (after | | | | | | | | | |
| water absorption - before | | | | | | | | | |
| water absorption) | | | | | | | | | |
| Amount of change in dielectric | 0.0124 | 0.0111 | 0.0107 | 0.0110 | 0.0083 | 0.0083 | 0.0089 | 0.0074 | 0.0174 |
| loss tangent (after water | | | | | | | | | |
| absorption - before | | | | | | | | | |
| water absorption) | | | | | | | | | |
| Coefficient of thermal | 110 | 138 | 79 | 75 | 74 | 77 | 109 | 153 | 113 |
| expansion (ppm/° C.) | | | | | | | | | |
| Dispersion | Uni- | Uni- | Unevenly | Uni- | Unevenly | Uni- | Uni- | Unevenly | Uni- |
| state | form | form | dis- | form | dis- | form | form | dis- | form |
| | | | tributed | | tributed | | | tributed | |

TABLE 2

| | | | Examples | | | | |
|---|---|---|---|---|---|---|---|
| | | | 8 | 9 | 10 | 11 | 12 |
| Composition | Maleimide compound | | 56 | 56 | 56 | 60 | 60 |
| (parts | Imide | Imide | — | — | — | 20 | 20 |
| by mass) | compound | compound-1 | | | | | |
| | | Imide | 30 | — | — | — | — |
| | | compound-3 | | | | | |
| | | Imide | — | 30 | — | — | — |
| | | compound-4 | | | | | |
| | | Imide | — | — | 30 | — | — |
| | | compound-5 | | | | | |
| | Radical | Benzoxazine | 14 | 14 | 14 | — | — |
| | polymerizable | compound | | | | | |
| | compound | Hydrocarbon-based | — | — | — | 20 | — |
| | | compound-1 | | | | | |
| | | Hydrocarbon-based | — | — | — | — | 20 |
| | | compound-2 | | | | | |
| | Reaction | PBP | 1 | 1 | 1 | 1 | 1 |
| | initiator | | | | | | |
| | Curing | 2E4MZ | 1 | 1 | 1 | — | — |
| | accelerator | | | | | | |
| | Inorganic | Silica | 40 | 40 | 40 | 40 | 40 |
| | filler | | | | | | |
| Evaluation | Before | Relative | 2.97 | 2.98 | 2.98 | 2.92 | 2.94 |
| | water | dielectric | | | | | |
| | absorption | constant | | | | | |
| | | Dielectric | 0.0036 | 0.0033 | 0.0031 | 0.0025 | 0.0025 |
| | | loss tangent | | | | | |
| | After | Relative | 3.12 | 3.14 | 3.11 | 3.09 | 3.12 |
| | water | dielectric | | | | | |
| | absorption | constant | | | | | |
| | | Dielectric | 0.0120 | 0.0130 | 0.0110 | 0.0130 | 0.0130 |
| | | loss tangent | | | | | |

| | | | | | |
|---|---|---|---|---|---|
| Amount of change in relative | 0.15 | 0.16 | 0.13 | 0.17 | 0.18 |
| dielectric constant (after | | | | | |
| water absorption - before | | | | | |
| water absorption) | | | | | |
| Amount of change in dielectric | 0.0084 | 0.0097 | 0.0079 | 0.0105 | 0.0105 |
| loss tangent (after water | | | | | |
| absorption - before | | | | | |
| water absorption) | | | | | |
| Coefficient of thermal | 100 | 68 | 102 | 77 | 78 |
| expansion (ppm/° C.) | | | | | |
| Dispersion | Uniform | Unevenly | Unevenly | Unevenly | Uniform |
| state | | distributed | distributed | distributed | |

As can be seen from Tables 1 and 2, in a case where the maleimide compound (A), the imide compound (B), and the radical polymerizable compound (C) were contained (Examples 1 to 12), there was obtained a resin composition that became a cured product, which had a lower relative dielectric constant and a lower dielectric loss tangent, sufficiently suppressed increases in relative dielectric constant and dielectric loss tangent due to water absorption, and a lower coefficient of thermal expansion, compared to cases (a case where a radical polymerizable compound different from the radical polymerizable compound (C) was contained: Comparative Example 1 and a case where the imide compound (B) was not contained: Comparative Example 2) other than this case.

This application is based on Japanese Patent Application No. 2022-107976 filed on Jul. 4, 2022, and the contents of which are included in the present application.

In order to express the present invention, the present invention has been described above appropriately and sufficiently through the embodiments. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

According to the present invention, there is provided a resin composition that affords a cured product, which has a low relative dielectric constant and a low dielectric loss tangent, sufficiently suppressed increases in relative dielectric constant and dielectric loss tangent due to water absorption, and a low coefficient of thermal expansion. In addition, the present invention provides a prepreg, a film with resin, a metal foil with resin, a metal-clad laminate, and a wiring board which are obtained using the resin composition.

1. A resin composition comprising:
a maleimide compound (A) having a benzene ring in a molecule and a maleimide equivalent of 500 g/mol or less;
an imide compound (B) having at least one of a hydrocarbon group or a maleimide group at a molecular end; and
a radical polymerizable compound (C) having a benzene ring to which an alkenyl group is bonded in a molecule and a weight average molecular weight of 1,000 or less.

2. The resin composition according to claim 1, wherein the imide compound (B) has a structure represented by following Formula (1) in a molecule: 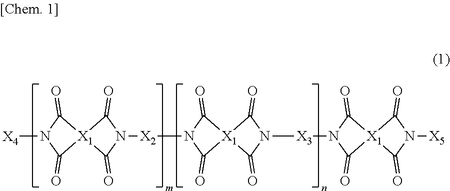
[in Formula (1), X₁ represents a tetravalent tetracarboxylic acid residue, X₂ represents a divalent aliphatic diamine residue, X₃ represents a divalent aromatic diamine residue, X₄ and X₅ each independently represent a hydrocarbon group having 1 to 20 carbon atoms, a maleimide group, or an acid anhydride group, at least one of X₄ or X₅ represents a hydrocarbon group having 1 to 20 carbon atoms or a maleimide group, m represents 1 to 50, n represents 0 to 49, and a sum of m and n represents 1 to 50].

3. The resin composition according to claim 1, wherein a weight average molecular weight of the imide compound (B) is 10,000 to 30,000.

4. The resin composition according to claim 1, wherein the maleimide compound (A) includes a maleimide compound having an arylene structure bonded in meta-orientation in a molecule.

5. The resin composition according to claim 1, wherein the alkenyl group in the radical polymerizable compound (C) includes at least one selected from the group consisting of an allyl group, a vinyl group, and a propenyl group.

6. The resin composition according to claim 1, wherein a content of the maleimide compound (A) is 30 to 70 parts by mass with respect to 100 parts by mass of a sum of the maleimide compound (A), the imide compound (B), and the radical polymerizable compound (C).

7. The resin composition according to claim 1, wherein a content of the imide compound (B) is 10 to 40 parts by mass with respect to 100 parts by mass of a sum of the maleimide compound (A), the imide compound (B), and the radical polymerizable compound (C).

8. The resin composition according to claim 1, further comprising an inorganic filler.

9. A prepreg comprising:
the resin composition according to claim 1 or a semi-cured product of the resin composition; and
a fibrous base material.

10. A film with resin comprising:
a resin layer containing the resin composition according to claim 1 or a semi-cured product of the resin composition; and
a support film.

11. A metal foil with resin comprising:
a resin layer containing the resin composition according to claim 1 or a semi-cured product of the resin composition; and
a metal foil.

12. A metal-clad laminate comprising:
an insulating layer containing a cured product of the resin composition according to claim 1; and
a metal foil.

13. A metal-clad laminate comprising:
an insulating layer containing a cured product of the prepreg according to claim 9; and
a metal foil.

14. A wiring board comprising:
an insulating layer containing a cured product of the resin composition according to claim 1; and
a wiring.

15. A wiring board comprising:
an insulating layer containing a cured product of the prepreg according to claim 9; and
a wiring.
